(19) United States
(12) Patent Application Publication
(10) Pub. No.: US 2009/0057789 A1
(43) Pub. Date: Mar. 5, 2009

(54) PACKAGE STRUCTURE FOR MICRO-SENSOR

(75) Inventors: Long Sun Huang, Taipei City (TW); Yung Shan Chiou, Taipei City (TW); Kuan Yi Lin, Taipei County (TW); Yi Kuang Yen, Kaohsiung City (TW); Chia Ming Hung, Taipei City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Long-Sun Huang, Taipei City (TW)

(21) Appl. No.: 12/186,388

(22) Filed: Aug. 5, 2008

(30) Foreign Application Priority Data
Sep. 5, 2007 (TW) 096133076

(51) Int. Cl. H01L 29/00

(52) U.S. Cl. 257/414; 257/E29.001

(57) ABSTRACT

The invention discloses a package structure for a micro-sensor including a micro-cantilever for capturing a chemical substance. The package structure, according to the invention, includes a first substrate, a second substrate, and a casing. The first substrate thereon forms a processing circuit. The micro-sensor is bonded to a first upper surface of the first substrate and is electrically connected to the processing circuit capable of outputting a signal relative to the chemical substance sensed by the micro-sensor. The second substrate has a formed-through aperture. The second substrate is bonded to the first substrate such that the micro-sensor is disposed in the formed-through aperture. The casing is bonded to the second substrate and includes a reaction chamber in which the micro-cantilever is installed and a fluid containing the chemical substance flows into.

### BACKGROUND OF THE INVENTION

1. Field of the Invention

The invention relates to a package structure. In particular, the invention relates to the package structure for a micro-sensor.

2. Description of the Prior Art

After marching into the time of our generation, which is featured by the increased senior population, the imbalanced distribution of medical resource, and the popular conception of disease prevention, the biological-sensor chips in recent year have been paid special attention in all walks of life. No matter it is in the academic circles or the industrial fields, people has actively invested large amount of money and manpower into the development and research of biological-sensor chips.

The conventional biomedicine examination system not only has the shortcomings including high cost, long examination time, occupying space, but it cannot be monitored online as well. However, as the biological nanometer technology develops so fast, the biological sensor instrument must be tinier, more sensitive, more portable, and should even be able to perform wireless transmission.

In the micro-biological sensor, a micro-cantilever biological sensor can utilize the resonance to measure the variation of the superficial mass besides being deflected by the surface stress which is generated by the molecular film. Additionally, the micro-cantilever biological sensor has the advantages of no-phosphor mark, high sensitivity, low cost and large amount of parallel examinations. Moreover, it is developing rapidly actively towards being tinier.

If the micro-cantilever biological sensor becomes a consumptive product, it is necessary that a suitable package structure protects the micro-cantilever biological sensor from the damage which is caused by the momentum of the external force, and makes it superior in portability. However, the suitable package structure is not seen at present. Therefore, the design and manufacturing of the package structure are really great problems of great urgency.

Accordingly, this invention provides a package structure for a micro-sensor to solve the aforementioned problems.

### SUMMARY OF THE INVENTION

A scope of the invention is to provide a package structure for a micro-sensor. The micro-sensor is used for sensing a chemical substance. The micro-sensor comprises a micro-cantilever for capturing the chemical substance.

According to an embodiment of the invention, the package structure comprises a first substrate, a second substrate, and a casing.

The first substrate thereon forms a processing circuit. The micro-sensor is bonded to a first upper surface of the first substrate and electrically connected to the processing circuit. The processing circuit can output a signal relative to the chemical substance sensed by the micro-sensor. The second substrate has a formed-through aperture. The second substrate is bonded to the first upper surface of the first substrate such that the micro-sensor is disposed in the formed-through aperture. The casing is bonded to the second substrate and includes a reaction chamber in which the micro-cantilever is installed and a fluid containing the chemical substance flows into.

Compared with prior art, according to the invention, the package structure not only protects the micro-cantilever biological sensor, but also makes it superior in portability. Furthermore, according to the invention the package structure can integrate with other external electrical device for more diversified applications.

The advantage and spirit of the invention may be understood by the following recitations together with the appended drawings.

### BRIEF DESCRIPTION OF THE APPENDED DRAWINGS

FIG. 1 illustrates a package structure of a micro-sensor according to an embodiment of the invention.

FIG. 2 illustrates a combination diagram of the package structure according to the invention.

FIG. 3 illustrates a diagram of the package structure which implements similar to a memory card according to the invention.

### DETAILED DESCRIPTION OF THE INVENTION

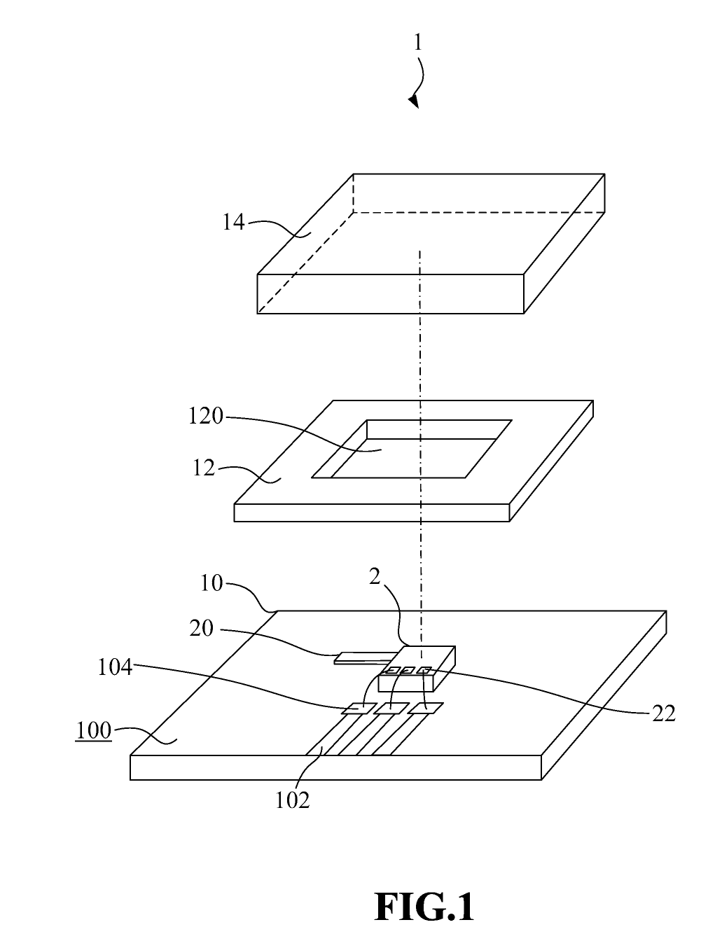

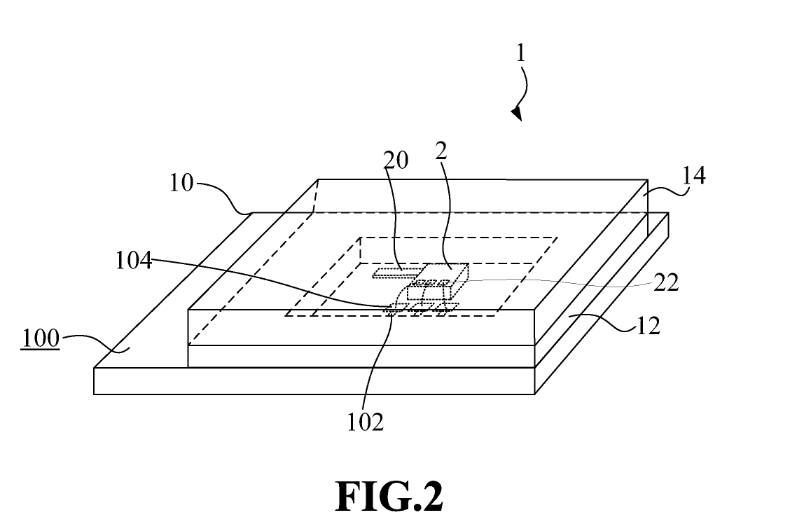

Please refer to FIG. 1 and FIG. 2. FIG. 1 illustrates a separated view graph of a package structure 1 for a micro-sensor 2 according to the invention. FIG. 2 illustrates a combination view graph of the package structure 1 according to the invention.

The micro-sensor 2 is used for sensing a chemical substance. In practical applications, the chemical substance can be a metal, a high polymer, a molecular biochemistry, a microorganism chemistry structure or the like.

As shown in FIG. 1, the micro-sensor 2 comprises a micro-cantilever 20 used for capturing the chemical substance. The package structure 1 comprises a first substrate 10, a second substrate 12, and a casing 14.

The first substrate 10 can be a printed circuit board (PCB). In this embodiment, the PCB is, but not limited to, a multi-layer PCB.

The first substrate 10 thereon forms a processing circuit 102. The micro-sensor 2 is bonded on a first upper surface 100 of the substrate 10, and electrically connects to the processing circuit 102. The processing circuit 102 can output a signal relative to the chemical substance sensed by the micro-sensor 2.

For example, after the micro-cantilever 20 captures the chemical substance, a deflection variation of the micro-cantilever 20 can be translated to the signal relative to the chemical substance. Then, the signal can be processed (i.e. filtering, amplifying signal, and so on) and outputted by the processing circuit 102.

In an embodiment, the micro-sensor 2 can be electrically connected to the processing circuit 102 by a wire-bonding. As shown in FIG. 1, the micro-sensor 2 and the first substrate 10 respectively have a bonding pad 104 and 22 for the wire-bonding.

Additionally, a conducting wire which connects to the micro-sensor 22 and the processing circuit 102 can be covered with an insulated material.

In another embodiment, the micro-sensor 2 can electrically connect to the processing circuit 102 on the first substrate 10 through a via. For example, the via can be formed in a substrate of the micro-sensor 2, but not limited to it.

The second substrate 12 has a formed-through aperture 120. The second substrate 12 is bonded to the first upper surface 100 of the first substrate 10, so as to make micro-sensor 2 disposed to the formed-through aperture 120. In this embodiment, the second substrate 12 can be made of silicon, but not limited to it.

The casing 14 is connected to the second substrate 12 and comprises a reaction chamber. The micro-sensor 2 is disposed in the reaction chamber, and a fluid containing the chemical substance flows into the reaction chamber. On the other hand, the casing 14 is a fluid channel used for the fluid. Additionally, as shown in the above illustration, the conducting wire which is connected to micro-sensor 2 and the processing circuit 102 is covered with insulated material, so as to insulate the conducting wire from the fluid.

In practical applications, the casing 14 can be made of a glass, a high polymer, a semiconductor material or the like. In this embodiment, the casing 14 is made of polydimethylsiloxane (PDMS) or the like.

In an embodiment, the first substrate 10 thereon forms a first connector, and the package structure 1 is detachably connected to a second connector of an external processing circuit by the first connector, such that a signal which is relative to the chemical substance is further outputted to external processing circuit by processing circuit 102.

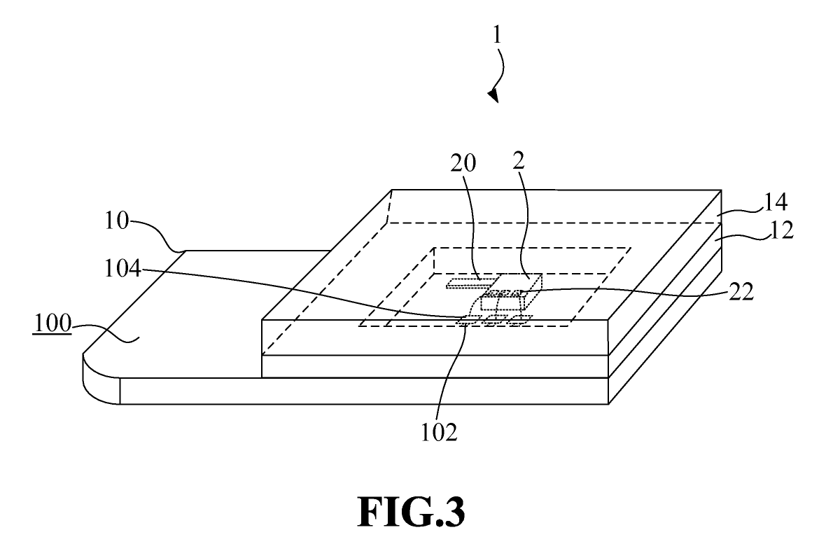

Please refer to FIG. 3. FIG. 3 shows a schematic diagram of the package structure 1, according to the invention, which is implemented as a memory card.

In this embodiment, the package structure 1, which is relative to the first upper surface 100 of the first substrate 10, can comprise a plurality of signal lines (not shown in FIG. 3). The plurality of signal lines can be used as the first connector. The package structure 1 is also detachably connected to a slot, like a general memory card, such that the signal relative to the chemical substance is outputted by the plurality of signal lines and the slot. The slot is used as the second connector.

Additionally, the package structure 1 can further comprise a physical sensor component and/or a chemical sensor component (not shown in FIG. 1 through FIG. 3). The physical sensor component can be used for detecting a temperature, a velocity of the fluid or a conductance in the reaction chamber, and so on. The chemical sensor component can be used for detecting the pH value or the ion concentration of the fluid, and so on. As far as functionality is concerned, the physical sensor component and the chemical sensor component can provide a variable which can probably influences the sensing result of the micro-sensor 2, and used for observing or correcting the variable.

Compared with prior art, according to the invention, the package structure not only can protect the micro-cantilever biosensor but it can also make it superior in portability. Furthermore, according to the invention, the package structure can integrate with another external electrical device, and increases on the variety of applications.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A package structure for a micro-sensor, the micro-sensor being used to sense a chemical substance and comprising a micro-cantilever for capturing the chemical substance, the package structure comprising:
a first substrate, a processing circuit being formed thereon, the micro-sensor being bonded to a first upper surface of the first substrate and electrically connected to the processing circuit, the processing circuit being capable of outputting a signal relative to the chemical substance sensed by the micro-sensor;
a second substrate having a formed-through aperture, the second substrate being bonded to the first upper surface of the first substrate, such that the micro-sensor is disposed in the formed-through aperture; and
a casing being bonded to the second substrate and comprising a reaction chamber, wherein the micro-sensor is disposed in the reaction chamber, and a fluid containing the chemical substance flows into the reaction chamber.

2. The package structure of claim 1, further comprising a physical sensor and/or a chemical sensor.

3. The package structure of claim 2, wherein a first connector is formed on the first substrate, and the package structure is detachably connected to a second connector of an external processing circuit by the first connector, such that the signal, which is relative to the chemical substance and outputted by the processing circuit, is further outputted to the external processing circuit.

4. The package structure of claim 3, wherein the first substrate is a printed circuit board.

5. The package structure of claim 1, wherein the micro-sensor is electrically connected to the processing circuit by wire-bonding.

6. The package structure of claim 5, wherein a conducting wire, which connects the micro-sensor and the processing circuit, is covered with an insulated material, so as to insulate the conducting wire from the fluid flowing into the reaction chamber.

7. The package structure of claim 1, wherein the micro-sensor is electrically connected to the processing circuit on the first substrate by a via.

8. The package structure of claim 7, wherein the via is formed in a substrate of the micro-sensor.

9. The package structure of claim 1, wherein the second substrate is made of silicon.

10. The package structure of claim 1, wherein the casing is made of one selected from the group consisting of a glass, a high polymer, and a semiconductor material.

11. The package structure of claim 10, wherein the casing is made of polydimethylsiloxane (PDMS).

12. The package structure of claim 1, wherein the chemical substance is one selected from the group consisting of a metal, a high polymer, a molecular biochemistry and a microorganism chemistry structure.
